(19) United States
(12) Patent Application Publication
(10) Pub. No.: US 2026/0293528 A1
(43) Pub. Date: Sep. 24, 2026

(54) PIEZOELECTRIC ELEMENT, LIQUID EJECTING HEAD, AND LIQUID EJECTING APPARATUS

(71) Applicant: SEIKO EPSON CORPORATION, Tokyo (JP)

(72) Inventors: Koji OHASHI, MATSUMOTO-SHI (JP); Nobuaki ITO, SUWA-SHI (JP); Yasuaki HAMADA, CHINO-SHI (JP); Masao NAKAYAMA, MATSUMOTO-SHI (JP)

(21) Appl. No.: 19/574,704

(22) Filed: Mar. 23, 2026

(30) Foreign Application Priority Data
Mar. 24, 2025 (JP) 2025-048865

(51) Int. Cl. H10N 30/85; B41J 2/14; H10N 30/50

(52) U.S. Cl. CPC H10N 30/852; B41J 2/14233; H10N 30/50; B41J 2002/14258

(57) ABSTRACT

A piezoelectric element includes, in this order in a stacking direction: a lower electrode; a lower piezoelectric body containing K, Na, and Nb; an upper piezoelectric body containing K, Na, and Nb; and an upper electrode, wherein K1/(K1+Na1)<K2/(K2+Na2) is satisfied, where K1 is an average concentration of K in the lower piezoelectric body, Na1 is an average concentration of Na in the lower piezoelectric body, K2 is an average concentration of K in the upper piezoelectric body, and Na2 is an average concentration of Na in the upper piezoelectric body.

The present application is based on, and claims priority from JP Application Serial Number 2025-048865, filed Mar. 24, 2025, the disclosure of which is hereby incorporated by reference herein in its entirety.

### BACKGROUND

### 1. Technical Field

The present disclosure relates to a piezoelectric element, a liquid ejecting head, and a liquid ejecting apparatus.

### 2. Related Art

An image forming apparatus including a liquid ejecting head that ejects a liquid such as ink onto a medium such as a print sheet has been proposed. As the liquid ejecting head, there is known a head which ejects a liquid filled in a pressure chamber from a nozzle by vibrating a vibration plate constituting a wall surface of the pressure chamber by using a piezoelectric element.

The piezoelectric element described in JP-A-2011-155272 includes a piezoelectric body composed of (KₐNa₁₋ₐ)NbO₃ containing K, Na, and Nb. (KₐNa₁₋ₐ)NbO₃ has a perovskite structure represented by a general formula ABO₃ and is abbreviated as KNN.

The KNN piezoelectric body has lower displacement characteristics, for example, than a lead zirconate titanate (PZT) piezoelectric body. Thus, in order to improve the displacement characteristics of the piezoelectric element, it is necessary to improve the displacement characteristics of the KNN piezoelectric body through stacking multiple layers. As a result of studies by the inventors, for example, a case where the KNN piezoelectric body has a multilayer structure having two layers of an upper layer and a lower layer is considered. In this case, it has been found that the upper layer and the lower layer having different compositions can provide a more preferable effect than the upper layer and the lower layer having the same composition.

### SUMMARY

According to an aspect of the present disclosure, a piezoelectric element includes, in this order in a stacking direction: a lower electrode; a lower piezoelectric body containing K, Na, and Nb; an upper piezoelectric body containing K, Na, and Nb; and an upper electrode, wherein K1/(K1+Na1)<K2/(K2+Na2) is satisfied, where K1 is an average concentration of K in the lower piezoelectric body, Na1 is an average concentration of Na in the lower piezoelectric body, K2 is an average concentration of K in the upper piezoelectric body, and Na2 is an average concentration of Na in the upper piezoelectric body.

According to an aspect of the present disclosure, a liquid ejecting head includes: the piezoelectric element; a pressure chamber through which a liquid flows and in which a pressure is applied to the liquid by the piezoelectric element; and a nozzle from which the liquid is ejected by the pressure applied in the pressure chamber.

According to an aspect of the present disclosure, a liquid ejecting apparatus includes: the liquid ejecting head; and a control unit that controls an ejection operation from the liquid ejecting head.

### BRIEF DESCRIPTION OF THE DRAWINGS

FIG. 1 is a schematic view illustrating a configuration of a liquid ejecting apparatus according to a first embodiment.

FIG. 2 is an exploded perspective view illustrating a liquid ejecting head illustrated in FIG. 1.

FIG. 3 is a cross-sectional view illustrating a portion of the liquid ejecting head illustrated in FIG. 2.

FIG. 4 illustrates a vibration plate and a piezoelectric element in FIG. 3.

FIG. 5 shows hysteresis curves.

FIG. 6 indicates the relation between electric field strength and capacitance for third and fourth examples in FIG. 5.

FIG. 7 is a table indicating the relation between K content and positive saturation polarization.

FIG. 8 is a graph indicating the relation between K content and positive saturation polarization.

FIG. 9 is a table showing Examples.

FIG. 10 is a table showing Comparative Examples.

### DESCRIPTION OF EMBODIMENTS

Hereinafter, preferred embodiments according to the present disclosure will be described with reference to the accompanying drawings. In the drawings, dimensions or scales of each component are different from the actual dimensions or scales as appropriate, and some portions are schematically illustrated for ease of understanding. In addition, the scope of the present disclosure is not limited to these embodiments unless it is noted in the following description that such embodiments limit the present disclosure. In addition, “an element α and an element β are stacked” means that the element α and the element β are arranged in the vertical direction, and it does not matter whether the element α and the element β are in direct contact with each other.

The following description will be made by using an X axis, a Y axis, and a Z axis that intersect each other, as appropriate. One direction along the X axis is referred to as an X1 direction, and a direction opposite to the X1 direction is referred to as an X2 direction. Directions opposite to each other along the Y axis are referred to as a Y1 direction and a Y2 direction. Directions opposite to each other along the Z axis are referred to as a Z1 direction and a Z2 direction. Viewing in a direction along the Z axis is referred to as “plan view”. The Z axis is typically a vertical axis. The Z1 direction is upward, and the Z2 direction is downward. However, the Z axis does not necessarily have to be the vertical axis. The X axis, the Y axis, and the Z axis are typically orthogonal to each other, but are not limited thereto, and only have to intersect each other at an angle within a range of, for example, 80° or more and 100° or less.

### 1. First Embodiment

### 1-1. Overall Configuration of Liquid Ejecting Apparatus 100

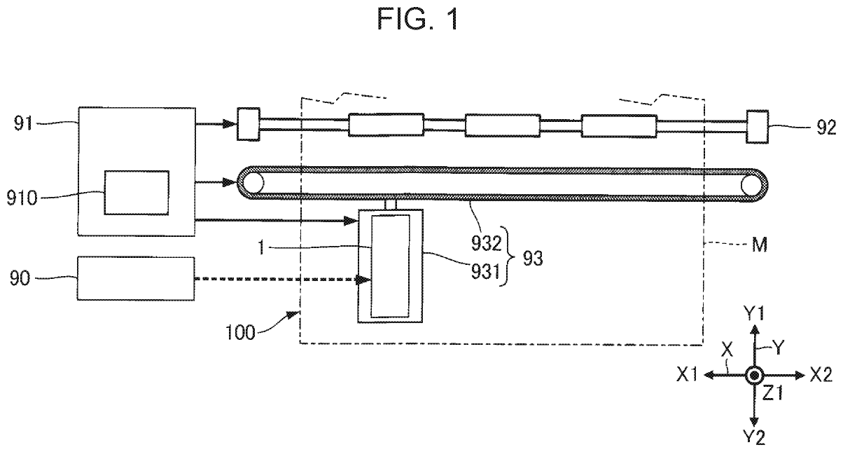

FIG. 1 is a configuration diagram schematically illustrating a liquid ejecting apparatus 100 according to a first embodiment. The liquid ejecting apparatus 100 is an ink jet printing apparatus that ejects ink, which is an example of a liquid, as droplets onto a medium M. The medium M is typically a print sheet. The medium M is not limited to a print sheet and may be, for example, a printing target of any material, such as a resin film or a cloth.

As illustrated in FIG. 1, the liquid ejecting apparatus 100 is equipped with a liquid container 90 for storing ink. Examples of the specific form of the liquid container 90 include a cartridge attachable to and detachable from the liquid ejecting apparatus 100, a bag-shaped ink pack formed of a flexible film, and an ink tank refillable with ink. A type of ink to be stored in the liquid container 90 is freely selected. The “liquid” may be any material that can be ejected from the liquid ejecting apparatus 100. For example, the “liquid” may be a material in which a solid substance is contained in a liquid.

The liquid ejecting apparatus 100 includes a control unit 91, a transport mechanism 92, a moving mechanism 93, and the liquid ejecting head 1. The control unit 91 includes, for example, a processing circuit such as a central processing unit (CPU) or a field programmable gate array (FPGA) and a storage circuit such as a semiconductor memory, and controls the operation of each component of the liquid ejecting apparatus 100. The control unit 91 includes a voltage application circuit 910 that causes ink to be ejected from a nozzle by controlling driving of a piezoelectric element 5, which will be described later. The voltage application circuit 910 applies a reference voltage VBS and a drive voltage Com to the piezoelectric element 5, which will be described later, included in the liquid ejecting head 1.

The transport mechanism 92 transports a medium M in the Y2 direction under the control of the control unit 91. The moving mechanism 93 reciprocates the liquid ejecting head 1 in the X1 direction and the X2 direction under the control of the control unit 91. In the example illustrated in FIG. 1, the moving mechanism 93 includes a substantially box-shaped transport body 931 called a carriage that accommodates the liquid ejecting head 1, and a transport belt 932 to which the transport body 931 is fixed. The number of liquid ejecting heads 1 mounted on the transport body 931 is not limited to one, and may be two or more. The liquid container 90 may be mounted on the transport body 931 in addition to the liquid ejecting head 1.

The liquid ejecting head 1 ejects ink supplied from the liquid container 90 onto the medium M in the Z2 direction from each of the nozzles under the control of the control unit 91. The ejection is performed in parallel with the transport of the medium M by the transport mechanism 92 and the reciprocating movement of the liquid ejecting head 1 by the moving mechanism 93, and thus an image is formed by the ink on a surface of the medium M.

The liquid ejecting apparatus 100 includes the liquid ejecting head 1, which will be described later, and the control unit 91, which controls an ejection operation from the liquid ejecting head 1. Since the liquid ejecting apparatus 100 includes the liquid ejecting head 1 having the characteristics described later, it is possible to reduce a decrease in piezoelectric characteristics and the occurrence of a drive delay. Thus, according to the liquid ejecting apparatus 100, it is possible to reduce a decrease in ejection performance.

### 1-2. Overall Configuration of Liquid Ejecting Head 1

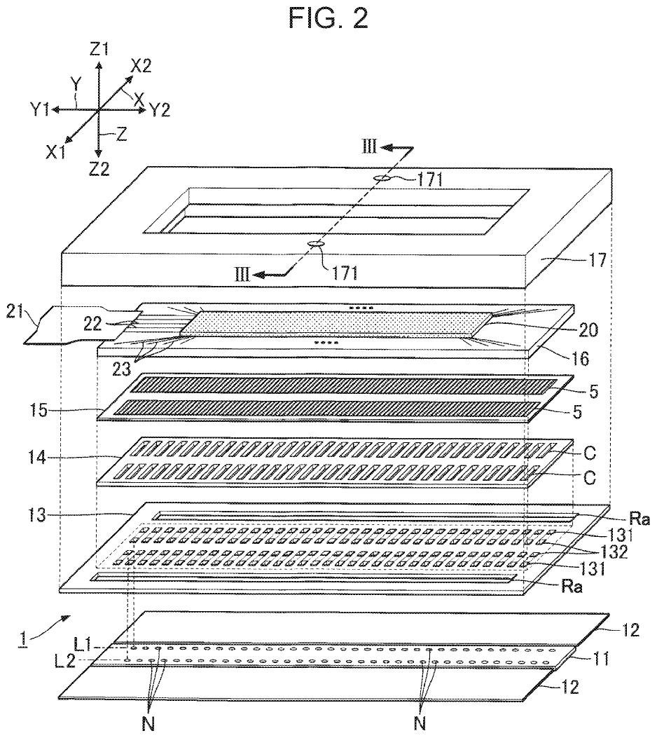

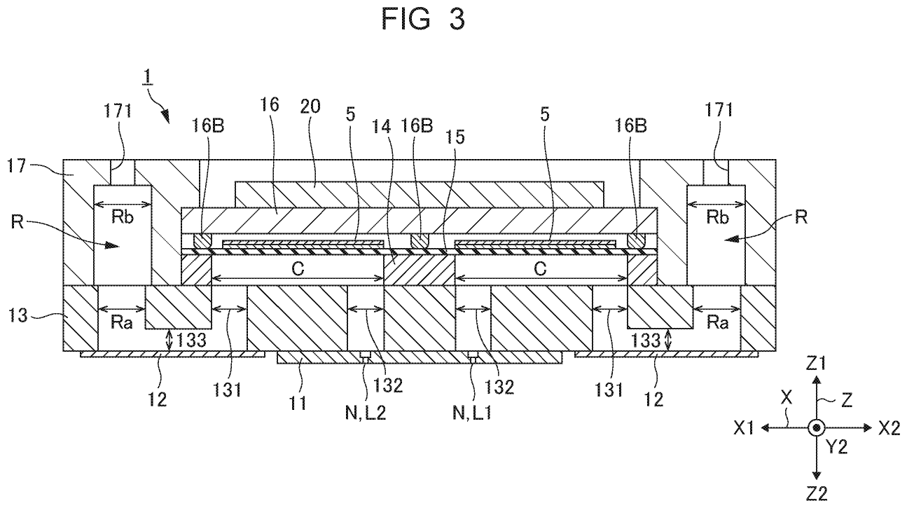

FIG. 2 is an exploded perspective view of the liquid ejecting head 1 illustrated in FIG. 1. FIG. 3 is a cross-sectional view of a portion of the liquid ejecting head 1 illustrated in FIG. 2, and is a cross-sectional view taken along line III-III in FIG. 2.

As illustrated in FIG. 2, the liquid ejecting head 1 includes a plurality of nozzles N arranged in a direction along the Y axis. In the example illustrated in FIG. 2, the nozzles N are divided into a first row L1 and a second row L2 which are arranged at intervals in the direction along the X axis. Each of the first row L1 and the second row L2 is a set of the plurality of nozzles N linearly arranged in the direction along the Y axis. The elements related to the nozzles N of the first row L1 and the elements related to the nozzles N of the second row L2 in the liquid ejecting head 1 are substantially symmetrical to each other in the direction along the X axis. In the following description, the elements corresponding to the first row L1 will be mainly described, and the description of the elements corresponding to the second row L2 will be omitted as appropriate.

The positions of the nozzles N in the first row L1 and the positions of the nozzles N in the second row L2 in the direction along the Y axis may coincide with each other or may be different from each other. Furthermore, the elements related to the nozzles N may be omitted from one of the first row L1 and the second row L2.

As illustrated in FIGS. 2 and 3, the liquid ejecting head 1 includes a nozzle plate 11, a vibration absorber 12, a flow path substrate 13, a pressure chamber substrate 14, a vibration plate 15, a wiring substrate 16, a housing 17, and a driving circuit 20. Each of the nozzle plate 11, the vibration absorber 12, the flow path substrate 13, the pressure chamber substrate 14, the vibration plate 15, the wiring substrate 16, and the housing 17 is a plate-shaped member that is elongated in the direction along the Y axis. The nozzle plate 11, the flow path substrate 13, the pressure chamber substrate 14, the vibration plate 15, and the wiring substrate 16 are arranged in this order in the Z1 direction.

The nozzle plate 11 is a plate-shaped member having the nozzles N. Each of the nozzles N is a circular through hole through which ink passes. Ink is ejected through the nozzles N by vibration of the vibration plate 15. The nozzle plate 11 is attached to the flow path substrate 13 using, for example, an adhesive. The nozzle N is a portion through which a liquid is ejected by the pressure applied in the pressure chamber C.

The flow path substrate 13 has flow paths for supplying ink to the nozzles N. Specifically, the flow path substrate 13 has spaces Ra, a plurality of supply flow paths 131, a plurality of communication flow paths 132, and supply liquid chambers 133. The space Ra is an opening having an elongated shape extending in the direction along the Y axis in plan view in the direction along the Z axis. The supply flow paths 131 and the communication flow paths 132 are through holes provided for corresponding nozzles N. The supply liquid chamber 133 is a space having an elongated shape extending in the direction along the Y axis over the nozzles N and allows the space Ra and the supply flow paths 131 to be in communication with each other. Each of the communication flow paths 132 overlaps one of nozzles N corresponding to the communication flow path 132 in plan view. The pressure chamber substrate 14 is attached to the flow path substrate 13 using, for example, an adhesive.

The pressure chamber substrate 14 has a plurality of pressure chambers C. The pressure chambers C are arranged in the direction along the Y axis. The pressure chambers C are provided for the corresponding nozzles N and are spaces having an elongated shape extending in the direction along the X axis in plan view. The pressure chamber C is a space located between the flow path substrate 13 and the vibration plate 15. The pressure chamber C is in communication with the nozzles N with the communication flow path 132 therebetween and in communication with the space Ra with the supply flow path 131 and the supply liquid chamber 133 therebetween. The pressure chamber C is a portion through which a liquid flows and in which a pressure is applied to the liquid by the piezoelectric element 5.

The nozzle plate 11, the flow path substrate 13, and the pressure chamber substrate 14 are each produced by processing a silicon single-crystal substrate using, for example, dry etching or wet etching. However, other known methods may be used as appropriate for producing the nozzle plate 11, the flow path substrate 13, and the pressure chamber substrate 14.

The vibration plate 15 is disposed on a surface of the pressure chamber substrate 14 facing the Z1 direction. The vibration plate 15 is a plate-shaped member that can elastically vibrate.

A plurality of piezoelectric elements 5 corresponding to the nozzles N are disposed on a surface of the vibration plate 15 facing the Z1 direction. The piezoelectric elements 5 each have an elongated shape extending in the direction along the X axis in plan view. The piezoelectric elements 5 correspond to the pressure chambers C and are arranged in the direction along the Y axis. The piezoelectric element 5 is deformed by application of a voltage. When the vibration plate 15 vibrates in response to the deformation, the pressure in the pressure chamber C fluctuates, and thus the ink is ejected from the nozzle N.

The housing 17 is a case for storing ink to be supplied to the pressure chambers C. As illustrated in FIG. 3, the housing 17 has a space Rb. The space Rb of the housing 17 and the space Ra of the flow path substrate 13 are in communication with each other. A space including the space Ra and the space Rb functions as a liquid storage chamber R that is a reservoir storing ink to be supplied to the pressure chambers C. The ink is supplied to the liquid storage chamber R through an inlet 171 of the housing 17. The ink in the liquid storage chamber R is supplied to the pressure chamber C through the supply liquid chamber 133 and the supply flow path 131.

The vibration absorber 12 is a flexible film that forms a wall surface of the liquid storage chamber R. The vibration absorber 12 is a compliance substrate that absorbs the pressure fluctuation of the ink in the liquid storage chamber R.

The wiring substrate 16 is a plate-shaped member having wiring lines for electrically coupling the driving circuit 20 and the piezoelectric elements 5. A surface of the wiring substrate 16 facing the Z2 direction is attached to the vibration plate 15 with a plurality of conductive bumps 16B therebetween. In contrast, the driving circuit 20 is mounted on a surface of the wiring substrate 16 facing the Z1 direction. The driving circuit 20 is an integrated circuit (IC) chip that outputs the driving voltage Com and the reference voltage VBS for driving the piezoelectric elements 5.

As illustrated in FIG. 2, an end portion of an external wiring line 21 is attached to a surface of the wiring substrate 16 facing the Z1 direction. The external wiring line 21 is, for example, a coupling component, such as a flexible printed circuit (FPC) and a flexible flat cable (FFC). The wiring substrate 16 has a plurality of wiring lines 22 that electrically couple the external wiring line 21 to the driving circuit 20, and a plurality of wiring lines 23 that receive the driving voltage Com and the reference voltage VBS output from the driving circuit 20.

The wiring substrate 16 is not limited to a rigid substrate, and may be, for example, a flexible printed circuit (FPC) or a flexible flat cable (FFC). In this case, the wiring substrate 16 may also serve as the external wiring line 21.

In the liquid ejecting head 1, when the piezoelectric element 5 is flexurally deformed by application of a voltage, the vibration plate 15 is flexurally deformed, that is, vibrates in a direction in which the volume of the pressure chamber C decreases. This changes the pressure in the pressure chamber C, and thus the ink in the pressure chamber C is ejected from the nozzle N. After the ink ejection, the piezoelectric element 5 is restored to its original position.

The liquid ejecting head 1 includes the piezoelectric element 5, the pressure chamber C through which ink as a liquid flows and in which pressure is applied to the ink by the piezoelectric element 5, and the nozzle N from which the ink is ejected by the pressure applied in the pressure chamber C. Since the liquid ejecting head 1 includes the piezoelectric element 5 having characteristics to be described later, it is possible to reduce a decrease in piezoelectric characteristics and the occurrence of a drive delay.

Although the liquid ejecting head 1 includes all of the elements illustrated in FIG. 3, the constituent elements of the liquid ejecting head 1 does not necessarily have to include all of the elements, and may further include an additional element.

### 1-3. Vibration Plate 15 and Piezoelectric Element 5

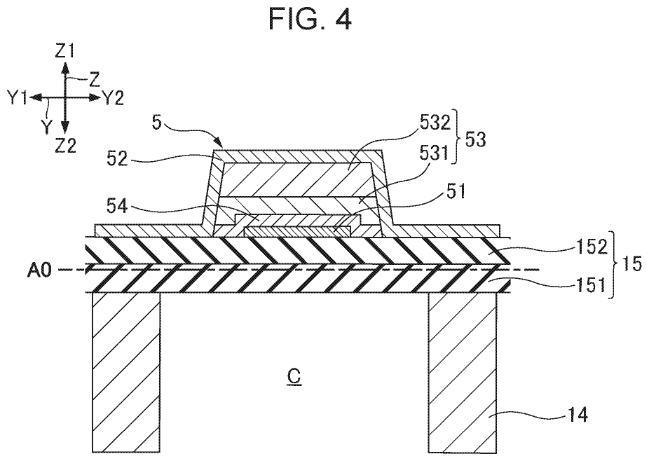

FIG. 4 is a cross-sectional view illustrating the vibration plate 15 and the piezoelectric element 5 of FIG. 3. In the example illustrated in FIG. 4, the vibration plate 15 has a multilayer structure including a first vibration body layer 151 and a second vibration body layer 152. The first vibration body layer 151 is in contact with the pressure chamber substrate 14. The second vibration body layer 152 is disposed above the first vibration body layer 151. The first vibration body layer 151 is formed of an elastic material such as silicon oxide (SiOₓ). The second vibration body layer 152 is formed of an insulating material such as zirconium oxide (ZrOₓ). The first vibration body layer 151 is formed by, for example, thermally oxidizing a portion of the pressure chamber substrate 14. The second vibration body layer 152 is formed by, for example, a known film forming technique such as sputtering. The vibration plate 15 may have one layer or three or more layers. In FIG. 4, a neutral axis A0 of the vibration plate 15 is also illustrated.

The piezoelectric element 5 is provided on the vibration plate 15. The piezoelectric element 5 mainly includes a lower electrode 51, a piezoelectric layer 53, an upper electrode 52, and a seed layer 54. The piezoelectric layer 53 includes a lower piezoelectric body 531 and an upper piezoelectric body 532. The lower electrode 51, the seed layer 54, the lower piezoelectric body 531, the upper piezoelectric body 532, and the upper electrode 52 are arranged in this order in the Z2 direction, which is the stacking direction.

The lower electrode 51 is provided above the vibration plate 15. The lower electrode 51 is an individual electrode provided for each of the piezoelectric elements 5. A drive voltage Com having a variable voltage is applied to the first lower electrode 51. The lower electrode 51 has an elongated shape extending along the X axis. The lower electrodes 51 are arranged along the Y axis at intervals. The lower electrode 51 includes a conductive material such as platinum (Pt), for example. The thickness of the lower electrode 51 along the Z axis is not particularly limited, but may be, for example, 50 nm or more and 120 nm or less. The lower electrode 51 may have one layer or two or more layers.

The seed layer 54 is provided to control the orientation of the piezoelectric layer 53. The thickness of the seed layer 54 along the Z axis is smaller than the thickness of the piezoelectric layer 53 along the Z axis. The thickness of the seed layer 54 along the Z axis is not particularly limited, but may be, for example, 5 nm or more and 50 nm or less. The seed layer 54 may have one layer or two or more layers.

For example, the seed layer 54 has a perovskite structure. The seed layer 54 contains, for example, lead titanate PbₐTi_{b}O_{z}, lanthanum nickelate LaₐNi_{b}O_{z}, PbₓBi₍ₐ₋ₓ₎Fe_{y}Ti_{(b-y})O_{z}, BiₐFe_{y}Ti_{(b-y)}O_{z}, or PbₐFe_{y}Ti_{(b-y)}O_{z}. In the above chemical formula, it is necessary to satisfy 0<x<a and 0<y<b. The seed layer 54 may contain a composite oxide having a perovskite structure containing Bi, Fe, and Ti. In particular, the seed layer 54 preferably contains PbₓBi₍ₐ₋ₓ₎Fe_{y}Ti_{(b-y)}O_{z}. PbₓBi₍ₐ₋ₓ₎Fe_{y}Ti_{(b-y)}O_{z} is particularly preferable because of its excellent orientation controllability.

The piezoelectric layer 53 is, for example, a band-shaped dielectric film that is continuous along the Y axis over the piezoelectric elements 5. The piezoelectric layer 53 has, for example, a band shape extending along the Y axis, and is separated for each of the piezoelectric elements 5 by having cutouts. The thicknesses of the piezoelectric layer 53 along the Z axis is not particularly limited, but is, for example, 300 nm or more and 1500 nm or less.

The upper electrode 52 is provided above the piezoelectric layer 53. The upper electrode 52 is a band-shaped common electrode continuously extending along the Y axis over the piezoelectric elements 5. A predetermined reference voltage VBS is applied to the upper electrode 52. The upper electrode 52 contains a conductive material such as iridium (Ir), for example. The thickness of the upper electrode 52 along the Z axis is not particularly limited, but may be, for example, 50 nm or more and 120 nm or less. The upper electrode 52 may have one layer or two or more layers.

In the piezoelectric element 5, a voltage corresponding to a difference between the reference voltage VBS applied to the upper electrode 52 and the drive voltage Com corresponding to the ejection amount and supplied to the lower electrode 51 is applied to the piezoelectric layer 53. When a voltage is applied between the lower electrode 51 and the upper electrode 52, the piezoelectric layer 53 is deformed, and thus the piezoelectric element 5 is flexurally deformed, that is, vibrates.

Although the lower electrode 51 is an individual electrode and the upper electrode 52 is a common electrode in the present embodiment, the lower electrode 51 may be a common electrode and the upper electrode 52 may be an individual electrode. cl 1-4. Piezoelectric Layer 53

The piezoelectric layer 53 has, for example, a multilayer structure having two or more layers. Specifically, as described above, the piezoelectric layer 53 includes the lower piezoelectric body 531 and the upper piezoelectric body 532.

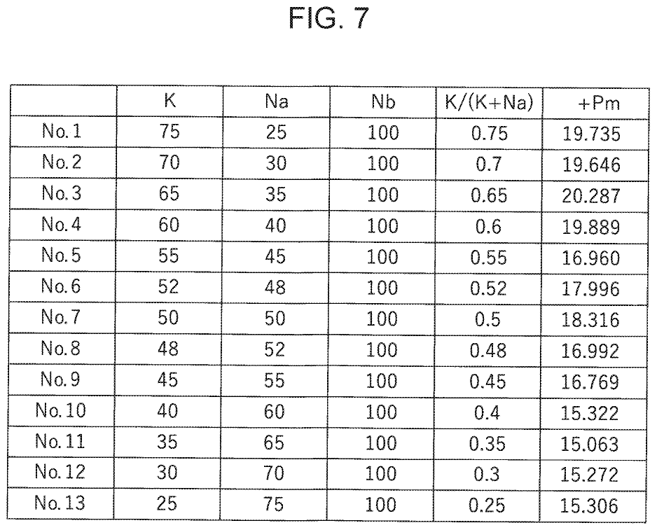

The lower piezoelectric body 531 may be formed of one layer or two or more layers. Similarly, the upper piezoelectric body 532 may be formed of one layer or two or more layers. However, as indicated in FIG. 7, which will be described later, the lower piezoelectric body 531 is formed of one material, and the upper piezoelectric body 532 is also formed of one material.

The lower piezoelectric body 531 contains K, Na, and Nb. Similarly, the upper piezoelectric body 532 contains K, Na, and Nb. Specifically, each of the lower piezoelectric body 531 and the upper piezoelectric body 532 has a perovskite structure containing K and Na in the A site and Nb in the B site. Specifically, each of the lower piezoelectric body 531 and the upper piezoelectric body 532 contains potassium sodium niobate ((KₐNa₁₋ₐ)NbO₃). (KₐNa₁₋ₐ)NbO₃ has a perovskite structure represented by a general formula ABO₃ and is abbreviated as KNN.

The lower piezoelectric body 531 and the upper piezoelectric body 532 may be produced by the same method or different methods. Each of the lower piezoelectric body 531 and the upper piezoelectric body 532 is produced by, for example, a MOD method, a sol-gel method, or a sputtering method. For example, the lower piezoelectric body 531 is produced by a sputtering method using a metal complex containing K, Na, and Nb, and the upper piezoelectric body 532 is produced by a sol-gel method. The sol-gel method involves applying a precursor solution composed of sol onto a substrate to form a piezoelectric precursor film, followed by drying at a predetermined temperature and degreasing. The MOD method involves applying an MOD solution to a substrate, followed by drying and degreasing. When the piezoelectric layer 53 is formed by a sol-gel process, a precursor solution containing K, Na, and Nb compounds is applied onto a substrate, followed by drying and calcination at a predetermined temperature to obtain a perovskite structure. In this case, the ratios of K, Na and Nb are controlled during solution preparation prior to coating and firing, and correspond to the intended composition of the resulting layer. Minor deviations after thermal treatment are acceptable within typical process tolerances.

As described above, the piezoelectric layer 53 includes the lower piezoelectric body 531 and the upper piezoelectric body 532. The piezoelectric layer 53 having this configuration can have improved displacement characteristics compared to a case where the piezoelectric layer 53 is formed of one piezoelectric body.

Furthermore, the upper piezoelectric body 532 is more distant from the neutral axis A0 than the lower piezoelectric body 531. Thus, the upper piezoelectric body 532 can cause the piezoelectric layer 53 to undergo a greater displacement than the lower piezoelectric body 531, even with a slight driving force. The upper piezoelectric body 532 contributes more to the displacement of the piezoelectric layer 53 than the lower piezoelectric body 531. Thus, the piezoelectric constant of the upper piezoelectric body 532 is preferably large. To increase the piezoelectric constant of the upper piezoelectric body 532, it is preferable to increase the saturation polarization Pm of the upper piezoelectric body 532.

In contrast, the lower piezoelectric body 531 less contributes to the displacement of the piezoelectric layer 53 than the upper piezoelectric body 532. However, the lower piezoelectric body 531 can also improve the displacement characteristics of the piezoelectric layer 53. From this point of view, it is conceivable to increase the saturation polarization Pm of the lower piezoelectric body 531 like the saturation polarization Pm of the upper piezoelectric body 532. However, the lower piezoelectric body 531 and the upper piezoelectric body 532 are connected in series. Thus, when both the saturation polarizations Pm of the lower piezoelectric body 531 and the upper piezoelectric body 532 are increased, the capacitance may be locally increased. This may prevent the high-frequency driving and cause a drive delay.

In view of the above, in order to achieve both the improvement of the displacement characteristics of the piezoelectric layer 53 and the reduction of occurrence of the drive delay in high-frequency driving, it is necessary to control the saturation polarization amount in each of the lower piezoelectric body 531 and the upper piezoelectric body 532. As a result of careful study by the inventors, it has been found that the saturation polarization amount can be controlled by setting the K/Na ratio for each of the lower piezoelectric body 531 and the upper piezoelectric body 532.

Specifically, the average concentration of K (potassium) in the lower piezoelectric body 531 is referred to as K1 [mol %], the average concentration of Na (sodium) in the lower piezoelectric body 531 is referred to as Na1 [mol %], the average concentration of K in the upper piezoelectric body 532 is referred to as K2 [mol %], and the average concentration of Na in the upper piezoelectric body 532 is referred to as Na2 [mol %]. In this case, the average concentrations K1, K2, Na1, and Na2 satisfy the following relation.

$$K 1 / ( K 1 + Na 1 ) < K 2 / ( K 2 + N a 2 )$$

That is, the K content of the A site of the upper piezoelectric body 532 is larger than the K content of the A site of the lower piezoelectric body 531.

When the average concentrations K1, K2, Na1, and Na2 satisfy the above relation, the saturation polarization Pm of the upper piezoelectric body 532 is larger than the saturation polarization Pm of the lower piezoelectric body 531. Thus, it is possible to reduce a local increase in capacitance caused by that both the saturation polarizations Pm of the upper piezoelectric body 532 and the lower piezoelectric body 531 increase in the same manner. Thus, it is possible to achieve both the improvement of the displacement characteristics of the piezoelectric layer 53 and the reduction of occurrence of the drive delay in high-frequency driving.

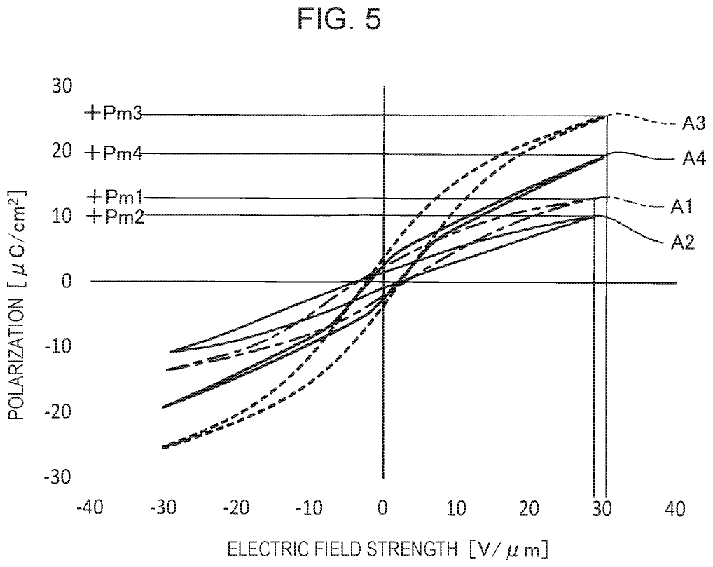

FIG. 5 is a diagram showing hysteresis curves. FIG. 5 indicates four types of hysteresis curves of a first example A1, a second example A2, a third example A3, and a fourth example A4. In FIG. 5, the horizontal axis represents electric field strength [V/μm], and the vertical axis represents polarization [μC/cm²]. In each hysteresis curve, a portion where the electric field strength is the highest corresponds to the positive saturation polarization +Pm. In FIG. 5, the positive saturation polarizations +Pm of the first example A1, the second example A2, the third example A3, and the fourth example A4 are indicated as positive saturation polarizations +Pm1, +Pm2, +Pm3, and +Pm4, respectively.

Each of the first example A1 and the second example A2 is a single-layer piezoelectric body formed of KNN. Specifically, in the single-layer piezoelectric body of the first example A1, K is 65 [mol %], and Na is 35 [mol %]. That is, the single-layer piezoelectric body of the first example A1 is formed of a K-rich piezoelectric body in which the ratio of K is higher than that of Na. In the single-layer piezoelectric body of the second example A2, K is 35 [mol %], and Na is 65 [mol %]. That is, the single-layer piezoelectric body of the second example A2 is formed of a Na-rich piezoelectric body in which the ratio of Na is higher than that of K.

As can be seen from the comparison between the first example A1 and the second example A2, the positive saturation polarization +Pm1 of the first example A1 is higher than the positive saturation polarization +Pm2 of the second example A2. Thus, it is understood that the K-rich piezoelectric body can have a higher positive saturation polarization +Pm than the Na-rich piezoelectric body.

The third example A3 is a piezoelectric layer 53x including a lower piezoelectric body and an upper piezoelectric body. In each of the lower piezoelectric body and the upper piezoelectric body in the third example A3, K is 65 [mol %], and Na is 35 [mol %]. The piezoelectric layer 53x of the third example A3 has a multilayer structure including two K-rich piezoelectric bodies. In the third example A3, the lower piezoelectric body and the upper piezoelectric body have the same K content.

The fourth example A4 is the piezoelectric layer 53 including the lower piezoelectric body 531 and the upper piezoelectric body 532. In the lower piezoelectric body 531 of the fourth example A4, K is 35 [mol %] and Na is 65 [mol %]. In the upper piezoelectric body 532 of the fourth example A4, K is 65 [mol%] and Na is 35 [mol%]. Thus, in the piezoelectric layer 53 of the fourth example A4, the K content of the upper piezoelectric body 532 is larger than the K content of the lower piezoelectric body 531. In the fourth example A4, the lower piezoelectric body 531 is formed of a Na-rich piezoelectric body, and the upper piezoelectric body 532 is formed of a K-rich piezoelectric body.

The positive saturation polarization +Pm3 of the third example A3 and the positive saturation polarization +Pm4 of the fourth example A4 are each higher than the positive saturation polarization +Pm1 of the first example A1 and the positive saturation polarization +Pm2 of the second example A2. Thus, the multilayer structure having the KNN piezoelectric bodies can increase the positive saturation polarization +Pm more than the single-layer structure of the KNN piezoelectric body. In particular, the third example A3 has the highest positive saturation polarization +Pm among the four examples. In other words, the positive saturation polarization +Pm can be particularly increased by the multilayer structure having two or more layers of the K-rich piezoelectric body. However, the positive saturation polarization +Pm4 of the fourth example A4 is higher than the positive saturation polarization +Pm1 of the first example A1 and the positive saturation polarization +Pm2 of the second example A2, but is lower than the positive saturation polarization +Pm3 of the third example A3.

The positive saturation polarization +Pm of the fourth example A4 is lower than that of the third example A3 and is higher than that of the first example A1. That is, in the multilayer structure having the lower layer and the upper layer having a higher K content than the lower layer, the positive saturation polarization +Pm is lower than that of the multilayer structure having the plurality of K-rich layers, but is higher than that of the single-layer structure having one K-rich layer.

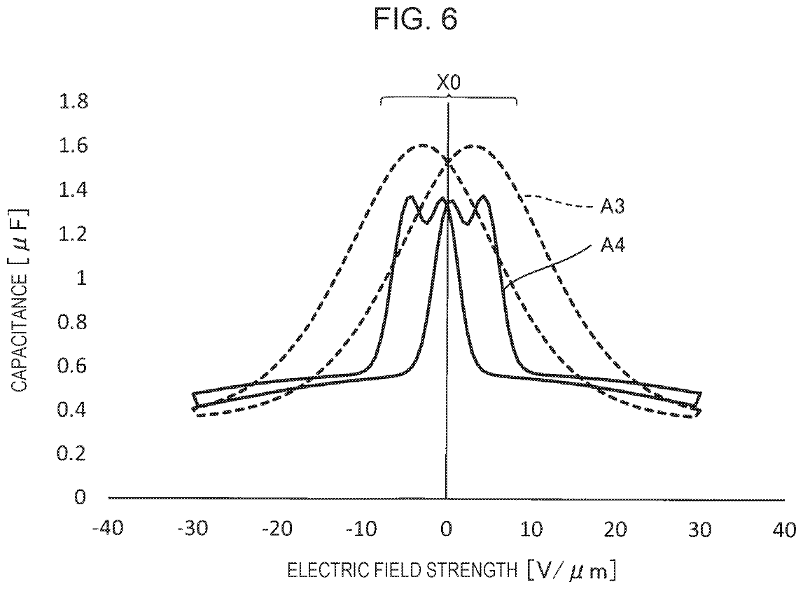

FIG. 6 is a diagram indicating the relation between the electric field strength and capacitance for the third example A3 and the fourth example A4 in FIG. 5. The horizontal axis of FIG. 6 represents electric field strength [V/μm], and the vertical axis represents capacitance [μF].

As indicated in FIG. 6, in the third example A3, the capacitance is locally large in the region X0. As in the third example A3, when both the saturation polarizations +Pm of the lower piezoelectric body 531 and the upper piezoelectric body 532 are increased, the capacitance is locally increased. This may prevent the high-frequency driving and cause a drive delay.

In contrast, in the fourth example A4, a local increase in the capacitance as in the third example A3 is not observed in the region X0. That is, by setting the K content of the upper piezoelectric body 532 larger than the K content of the lower piezoelectric body 531, as in the fourth example A4, the possibility of a drive delay can be reduced compared with the multilayer structure composed of a plurality of K-rich layers, as in the third example A3.

As can be seen from FIG. 5, by setting the K content of the upper piezoelectric body 532 larger than the K content of the lower piezoelectric body 531, the displacement characteristics can be improved compared to a case where the single-layer piezoelectric layer 53 is used. In addition, as can be seen from FIG. 6, by setting the K content of the upper piezoelectric body 532 larger than the K content of the lower piezoelectric body 531, the possibility of a drive delay can be reduced compared with a multilayer structure having a plurality of K-rich layers. That is, as can be seen from FIGS. 5 and 6, when the average concentrations K1, K2, Na1, and Na2 satisfy the relation of K1/(K1+Na1)<K2/(K2+Na2), the displacement characteristics can be improved, and the occurrence of a drive delay can be reduced in high-frequency driving.

As in the fourth example A4, the lower piezoelectric body 531 is preferably a Na-rich layer, and the upper piezoelectric body 532 is preferably a K-rich layer. That is, it is preferable that the average concentrations K1, K2, Na1, and Na2 satisfy the relation of K1/(K1+Na1)<0.50<K2/(K2+Na2). When the average concentrations K1, K2, Na1, and Na2 satisfy the above relation, it is possible to effectively achieve both the improvement of the displacement characteristics and the reduction of occurrence of the drive delay, compared to a case where the above relation is not satisfied.

The upper piezoelectric body 532 does not necessarily have to be a k-rich layer as long as the average concentrations K1, K2, Na1, and Na2 satisfy K1/(K1+Na1)<K2/(K2+Na2). Similarly, the lower piezoelectric body 531 does not necessarily have to be a Na-rich layer.

In addition, it is preferable that the average concentrations K1, K2, Na1, and Na2 satisfy 0.20≤K2/(K2+Na2)−K1/(K1+Na1)≤0.40. The average concentrations K1 and Na1 of the lower piezoelectric body 531 preferably satisfy the relation of K1/(K1+Na1)≤0.40. The average concentrations K1 and Na1 of the lower piezoelectric body 531 preferably satisfy K1/(K1+Na1)≥0.30. In addition, the average concentrations K2 and Na2 of the upper piezoelectric body 532 preferably satisfy K2/(K2+Na2)≥0.60. Furthermore, the average concentrations K2 and Na2 of the upper piezoelectric body 532 preferably satisfy K2/(K2+Na2)≤0.70. The reasons of theses will be described later.

Furthermore, when the average concentrations K1, K2, Na1, and Na2 satisfy the relation of K1/(K1+Na1)<K2/(K2+Na2) as described above, the saturation polarization Pm of the upper piezoelectric body 532 can be made larger than the saturation polarization Pm of the lower piezoelectric body 531. That is, the saturation polarization Pm of the lower piezoelectric body 531 can be made smaller than the saturation polarization Pm of the upper piezoelectric body 532. Since the saturation polarization Pm of the lower piezoelectric body 531 is smaller than the saturation polarization Pm of the upper piezoelectric body 532, it is possible to reduce a local increase in capacitance caused by that both the saturation polarizations Pm of the upper piezoelectric body 532 and the lower piezoelectric body 531 increase in the same manner. Thus, it is possible to effectively achieve both the improvement of the displacement characteristics of the piezoelectric layer 53 and the reduction of occurrence of the drive delay.

For example, the positive saturation polarization +Pm of the lower piezoelectric body 531 is preferably 15.5 [μC/cm²] or less. When the positive saturation polarization +Pm of the lower piezoelectric body 531 satisfies the above-described relation, it is possible to effectively reduce the drive delay of the piezoelectric element 5 compared to a case where the relation is not satisfied.

For example, the positive saturation polarization +Pm of the upper piezoelectric body 532 is preferably 19.5 [μC/cm²] or more. When the positive saturation polarization +Pm of the upper piezoelectric body 532 satisfies the above-described relation, it is possible to reduce a decrease in the displacement characteristics of the upper piezoelectric body 532 and the displacement characteristics of the piezoelectric element 5, compared to a case where the relation is not satisfied.

The positive saturation polarization +Pm of the lower piezoelectric body 531 may exceed 15.5 [μC/cm²]. Furthermore, the positive saturation polarization +Pm of the upper piezoelectric body 532 may be less than 19.5 [μC/cm²].

Furthermore, when the average concentration of Nb in the lower piezoelectric body 531 is Nb1 and the average concentration of Nb in the upper piezoelectric body 532 is Nb2, the average concentrations K1, K2, Na1, Na2, Nb1, and Nb2 preferably satisfy the following relation.

$$0.9 < \{ Nb 2 / ( K 2 + N a 2 + N b 2 ) \} / \{ Nb 1 / ( K 1 + Na 1 + Nb 1 ) \} < 1.10$$

The fact that the average concentrations K1, K2, Na1, Na2, Nb1 and Nb2 satisfy the above-described relation means that there is substantially no difference in the Nb content of the B site between the lower piezoelectric body 531 and the upper piezoelectric body 532, and the average concentrations K1, K2, Na1 and Na2 satisfy the relation of K1/(K1+Na1)<K2/(K2+Na2). When the difference between the Nb content of the lower piezoelectric body 531 and the Nb content of the upper piezoelectric body 532 is excessively large, the lower piezoelectric body 531 and the upper piezoelectric body 532 may be separated from each other.

Furthermore, the upper piezoelectric body 532 is preferably thicker than the lower piezoelectric body 531. These thicknesses are lengths in the Z2 direction, which corresponds to the stacking direction. The upper piezoelectric body 532 greatly affects the displacement characteristics of the piezoelectric element 5. Thus, the upper piezoelectric body 532, which is thicker than the lower piezoelectric body 531, can improve the displacement characteristics of the piezoelectric element 5 compared to a case where the upper piezoelectric body 532 is thin.

The thickness of the upper piezoelectric body 532 may be equal to or less than the thickness of the lower piezoelectric body 531.

Hereinafter, examples of the piezoelectric layer 53 will be described with reference to Examples and Comparative Examples.

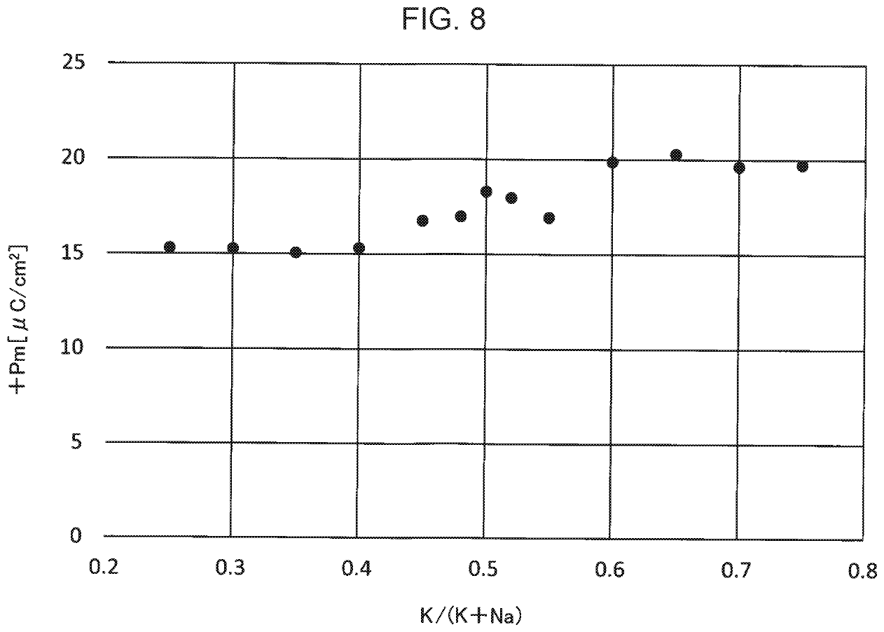

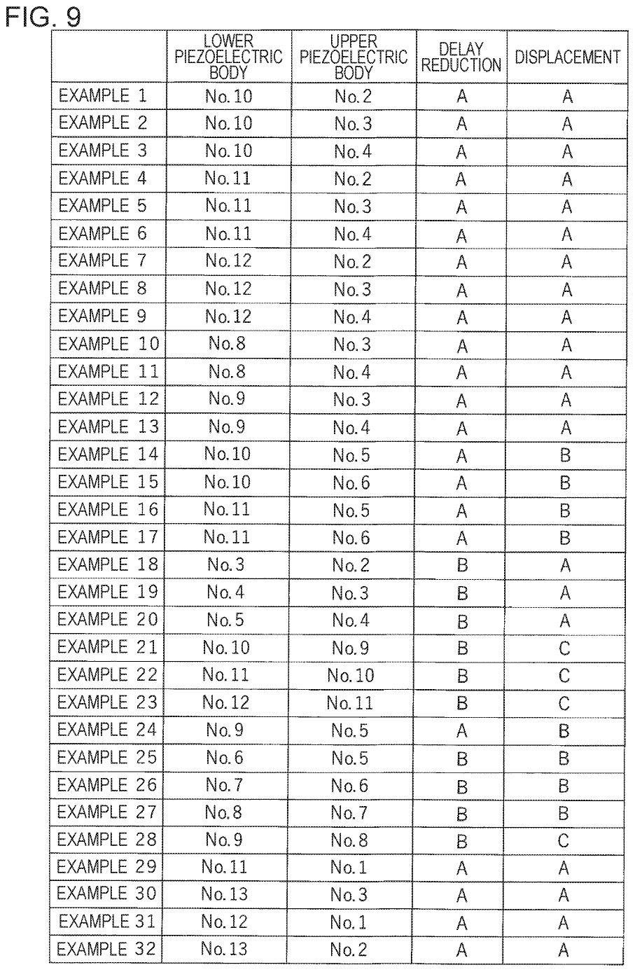

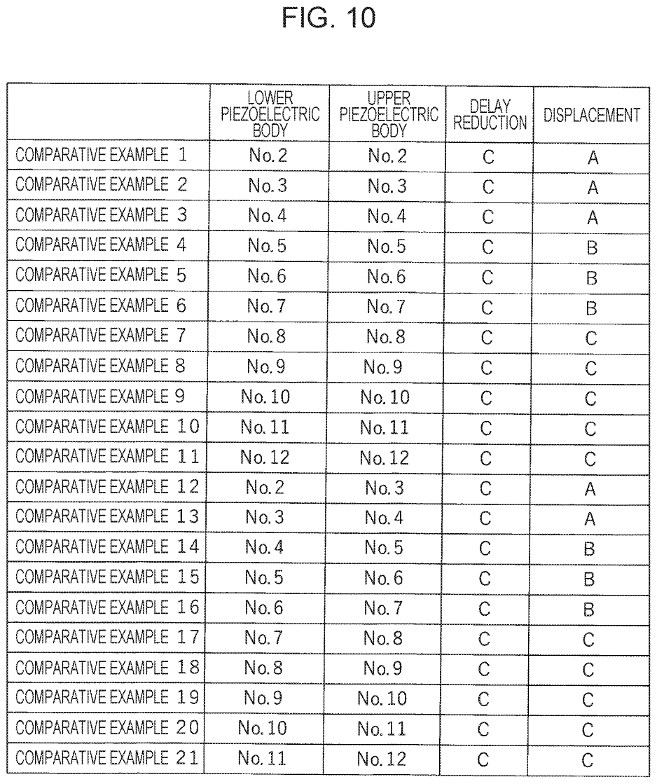

FIG. 7 is a table indicating the relation between the K content and the positive saturation polarization +Pm. FIG. 8 is a graph indicating the relation between the K content and the positive saturation polarization +Pm. FIG. 9 is a table showing Examples. FIG. 10 is a table showing Comparative Examples. As the lower piezoelectric body and the upper piezoelectric body in Examples of FIG. 9 and Comparative Examples of FIGS. 10, 13 types of KNN piezoelectric bodies of No. 1 to No. 13 indicated in FIG. 7 are used.

FIG. 7 indicates the average concentrations of K, Na, Nb, K/(K+Na), and the positive saturation polarization +Pm for 13 types of KNN piezoelectric bodies of No. 1 to No. 13. The 13 types of KNN piezoelectric bodies of No. 1 to No. 13 each have a single layer. Although the 13 types of KNN piezoelectric bodies of No. 1 to No. 13 are single-layer piezoelectric bodies, multi-layer KNN piezoelectric bodies formed by the same production method and having the same composition showed substantially the same tendency as the values indicated in FIG. 7.

In No. 1 to No. 6, the average concentration of K is higher than the average concentration of Na. Among No. 1 to No. 6, No. 1 has the highest average concentration of K, and the average concentration of K decreases from No. 1 to No. 6. In No. 7 the average concentration of K and the average concentration of Na are equal to each other. In No. 8 to No. 13, the average concentration of K is lower than the average concentration of Na. Among No. 8 to No. 13, No. 13 has the lowest average concentration of K, and the average concentration of K decreases from No. 8 to No. 13.

FIG. 8 indicates the relation between the K content and the positive saturation polarization +Pm of No. 1 to No. 13 in FIG. 7. In FIG. 8, the horizontal axis represents K/(K+Na), and the vertical axis represents the positive saturation polarization +Pm. For example, the rightmost data point in FIG. 8 is No. 1. The leftmost data point in FIG. 8 is No. 13.

As indicated in FIGS. 7 and 8, No. 1 to No. 6 have a larger positive saturation polarization +Pm than No. 8 to No. 13. Since the positive saturation polarization +Pm can be increased by increasing the K content, the piezoelectric constant can be increased, improving the displacement characteristics.

As indicated in FIGS. 9 and 10, in the piezoelectric layers of Examples and Comparative Examples, any one of the KNN piezoelectric bodies of No. 1 to No. 13 in FIG. 7 was used as the upper piezoelectric body and the lower piezoelectric body.

For example, in Example 1, No. 10 was used as the lower piezoelectric body, and No. 2 was used as the upper piezoelectric body. Specifically, in the lower piezoelectric body of Example 1, the average concentration K1 is 40 [mol %], and the average concentration Na1 is 60 [mol %]. In the upper piezoelectric body of Example 1, the average concentration K2 is 70 [mol %], and the average concentration Na2 is 30 [mol %]. Thus, in Example 1, the K content of the upper piezoelectric body is higher than the K content of the lower piezoelectric body.

As in Example 1, in each of Examples 2 to 32, the K content of the upper piezoelectric body is higher than the K content of the lower piezoelectric body. That is, each of Examples 1 to 32 satisfies K1/(K1+Na1)<K2/(K2+Na2). In contrast, in each of Comparative Examples 1 to 21, the K content of the upper piezoelectric body is equal to or less than the K content of the lower piezoelectric body. That is, each of Comparative Examples 1 to 21 does not satisfy K1/(K1+Na1)<K2/(K2+Na2).

In Examples 1 to 32, the saturation polarization Pm of the lower piezoelectric body is smaller than the saturation polarization Pm of the upper piezoelectric body. According to each of Examples, it is possible to achieve both the improvement of the displacement characteristic of the piezoelectric layer and the reduction of occurrence of the drive delay in the high-frequency driving, compared to Comparative Examples.

The lower electrode has the same configuration in Examples and Comparative Examples. Similarly, the upper electrode has the same configuration in Examples and Comparative Examples. In addition, the thickness of the upper piezoelectric body is the same in Examples and Comparative Examples. The thickness of the lower piezoelectric body is the same in Examples and Comparative Examples.

FIGS. 9 and 10 indicate the evaluation results regarding delay reduction and the evaluation results regarding displacement.

### Evaluation Method of Drive Delay Reduction

The delay reduction was evaluated based on unevenness of an image when the piezoelectric element was driven at a predetermined driving frequency. In this evaluation, for example, the predetermined driving frequency is 60 kHz. The evaluation was made using the following three grades A, B and C.
A: Almost no unevenness was observed in the image formed by one scanning when the piezoelectric element was driven at 60 kHz.
B: Slight unevenness was observed in the scanning direction in the image formed by one scanning when the piezoelectric element was driven at 60 kHz.
C: Frequent unevenness was observed in the scanning direction in an image formed by one scanning when the piezoelectric element was driven at 60 kHz.

When the driving is delayed, the ejection timing is delayed. As a result, the dot formed on the medium deviates from the ideal landing position to a position downstream in the scanning direction. When all the dots in the scanning direction are going to be formed at equal intervals, such a deviation of the landing positions is recognized as unevenness of the image.

### Displacement Characteristics Evaluation Method

The displacement characteristics were evaluated based on a deviation from an ideal ejection amount. The ideal ejection amount refers to the amount of ink intended to be ejected per ejection. In this evaluation, for example, the ideal ejection amount is 1.5 pl.
A: There was almost no shortage of the ejection amount relative to the ideal ejection amount.
B: There was a shortage of 3% or more and less than 10% relative to the ideal ejection amount in some cases.
C: There was a shortage of 10% or more relative to the ideal ejection amount in some cases.

In particular, in Examples 1 to 17, 24, 29, and 30, the upper piezoelectric body is a K-rich layer, and the lower piezoelectric body is a Na-rich layer. That is, in Examples 1 to 17, 24, 29, and 30, the average concentrations K1, K2, Na1, and Na2 satisfy the following relation of Expression 1.

$$K 1 / ( K 1 + Na 1 ) < 0.5 < K 2 / ( K 2 + N a 2 ) \qquad Expression 1$$

In Examples 1 to 17, 24, and 29 to 32, the evaluation regarding the delay reduction was A, and there was almost no unevenness in the image. In addition, in Examples 1 to 17, 24, 29, and 30, the evaluation regarding the displacement characteristics was A or B, and there was almost no shortage of the ejection amount relative to the ideal ejection amount, or even if there was, it was less than 10%. As described above, in Examples 1 to 17, 24, and 29 to 32, it was possible to prevent the drive delay in the high-frequency driving and also to reduce the defect of the ejection amount within the allowable range.

In addition, it is preferable that the difference in the K content of the A site between the upper piezoelectric body and the lower piezoelectric body, that is, K2/(K2+Na2)−K1/(K1+Na1) be not too large. This is because if this difference is too large, the saturation polarization Pm is also greatly different between the upper piezoelectric body and the lower piezoelectric body, which increases the difference in the degree of strain, and there is a risk that separation will occur between the upper piezoelectric body and the lower piezoelectric body. Specifically, it is preferable that the following Expression 2 be satisfied.

$$K 2 / ( K 2 + N a 2 ) - K 1 / ( K 1 + N a 1 ) \leq 0.40 \qquad Expression 2$$

However, it is also not preferable that the difference in the K content of the A site be too small. The small difference means that the composition ratio of the A site is not largely different between the upper piezoelectric body and the lower piezoelectric body. In the first place, the upper piezoelectric body and the lower piezoelectric body are members to be stacked and have the same composition at the A site, namely K and Na. Thus, even if the relative quantities of the compositions are varied, a phenomenon in which elements migrate between the piezoelectric bodies over time to flatten the compositional ratio occurs. When the difference in the K content of the A site is too small, even if the drive delay or the displacement characteristic deterioration can be reduced at first, the influence of the element migration cannot be sufficiently canceled, and thus a problem may occur after the use for a certain long period of time. Specifically, it is preferable that the following Expression 3 be satisfied.

$$0.2 \leq K 2 / ( K 2 + Na2 ) - K 1 / ( K 1 + Na 1 ) \qquad Expression 3$$

Summarizing these, it is preferable that the difference in the K content of the A site be not too large and not too small, that is, summarizing Expression 2 and Expression 3, it is preferable that the following Expression 4 be satisfied.

$$0.20 \leq K 2 / ( K 2 + N a 2 ) - K 1 / ( K 1 + N a 1 ) \leq 0.40 \qquad Expression 4$$

Examples 1 to 9, 12, 16, 29, and 30 satisfy Expression 4. These Examples did not have a problem of separation between the piezoelectric layers and a problem associated with long-term use. In contrast, for example, Examples 31 and 32, which satisfy K2/(K2+Na2)−K1/(K1+Na1)>0.40, had a problem of separation between the upper piezoelectric body and the lower piezoelectric body in some cases. In addition, for example, Examples 10 to 11, 13 to 15, and 17 to 28, which satisfy K2/(K2+Na2)−K1/(K1+Na1)<0.20, had a drive delay or displacement characteristic deterioration because of long-term use in some cases.

Here, in order to satisfy both Expression 1 and Expression 3, it is found that K1/(K1+Na1) and K2/(K2+Na2) only have to exceed the range of ±0.10 from 0.50. Specifically, it is preferable that Expression 5 and Expression 6 be satisfied.

$$K 1 / ( K 1 + Na 1 ) \leq 0.4 \qquad Expression 5$$

$$K 2 / ( K 2 + Na 2 ) \geq 0.60 \qquad Expression 6$$

Examples 1 to 9, 14 to 17, 21 to 23, and 29 to 32 satisfy Expression 5. Furthermore, Examples 1 to 13, 18 to 20, and 29 to 32 satisfy Expression 6.

In addition, in order to satisfy both Expression 1 and Expression 2, it is found that K1/(K1+Na1) and K2/(K2+Na2) only have to be within the range of ±0.20 from 0.50. Specifically, it is preferable that Expression 8 be satisfied in addition to Expression 7 and that Expression 6 be satisfied in addition to Expression 5.

$$K 1 ( K 1 + Na 1 ) \geq 0.3 \qquad Expression 7$$

$$K 2 ( K 2 + Na 2 ) \leq 0.7 \qquad Expression 8$$

Examples 1 to 9, 14 to 17, 21 to 23, 29, and 31 satisfy Expression 5 and Expression 7. Furthermore, Examples 1 to 13, 18 to 20, 30, and 32 satisfy Expression 6 and Expression 8.

As described above, it is necessary for the present disclosure to satisfy K1/(K1+Na1)<K2/(K2+Na2). However, summarizing Expression 1 to Expression 8, it is more preferable that 0.30≤K1/(K1+Na1)≤0.40 and 0.60≤K2/(K2+Na2)≤0.70 be satisfied. Examples 1 to 9 satisfy the above expression.

As described above, when the value of Nb in the B site is largely different between the upper piezoelectric body and the lower piezoelectric body, separation may occur between the piezoelectric bodies. Thus, in Examples 1 to 32, both are set to be substantially equal. Specifically, Examples 1 to 32 satisfy 0.90<{Nb2/(K2+Na2+Nb2)}/{Nb1/(K1+Na1+Nb1)}<1.10.

### 2. Modifications

The above-described embodiments may be modified in various ways. Specific modifications applicable to the above-described embodiments will be described later. Any two or more aspects selected from the following examples can be appropriately combined within a range in which they do not contradict each other.

The “liquid ejecting head” may be a circulation head having a so-called circulation flow path.

The “image forming apparatus” may be adopted in various devices such as facsimile devices and copy machines, in addition to devices dedicated to printing. The use of the image forming apparatus is not limited to printing. For example, an image forming apparatus that ejects a solution of a coloring material is used as a manufacturing apparatus that forms a color filter of a display device such as a liquid crystal display panel. In addition, an image forming apparatus that ejects a solution of a conductive material is used as a manufacturing apparatus that forms wiring lines or electrodes on a wiring substrate. In addition, an image forming apparatus that ejects a solution of an organic substance relating to a living body is used as, for example, a manufacturing apparatus that produces biochips.

The piezoelectric element according to the present disclosure is not limited to application in the liquid ejecting head or the liquid ejecting apparatus and is applicable to any device that has the function of converting between voltage and mechanical force: mechanical force is generated upon application of voltage and voltage is generated upon application of mechanical force. The piezoelectric element according to the present disclosure may be used in, for example, an ultrasonic motor, a vibration-type dust removing device, a piezoelectric transformer, a piezoelectric speaker, a piezoelectric pump, an ultrasonic detector, an angular velocity sensor, an acceleration sensor, a vibration sensor, an inclination sensor, a pressure sensor, a collision sensor, a motion sensor, an infrared sensor, a terahertz sensor, a heat detection sensor, a pyroelectric sensor, a piezoelectric sensor, a ferroelectric memory (FeRAM), a ferroelectric transistor (FeFET), a ferroelectric arithmetic circuit (FeLogic), a ferroelectric capacitor, a wavelength converter, an optical waveguide, an optical path modulator, a refractive index control element, or an electronic shutter mechanism.

Although the present disclosure has been described above based on the preferred embodiments, the present disclosure is not limited to the above-described embodiments. In addition, the configuration of each portion of the present disclosure can be replaced with any configuration having the same function as that in the above-described embodiments, and any configuration can be added.

What is claimed is:

1. A piezoelectric element comprising, in this order in a stacking direction:
a lower electrode;
a lower piezoelectric body containing K, Na, and Nb;
an upper piezoelectric body containing K, Na, and Nb; and
an upper electrode, wherein
K1/(K1+Na1)<K2/(K2+Na2) is satisfied, where
K1 is an average concentration of K in the lower piezoelectric body,
Na1 is an average concentration of Na in the lower piezoelectric body,
K2 is an average concentration of K in the upper piezoelectric body, and
Na2 is an average concentration of Na in the upper piezoelectric body.

2. The piezoelectric element according to claim 1, wherein K1/(K1+Na1)<0.50<K2/(K2+Na2) is satisfied.

3. The piezoelectric element according to claim 1, wherein 0.20≤K2/(K2+Na2)−K1/(K1+Na1)≤0.40 is satisfied.

4. The piezoelectric element according to claim 1, wherein K1/(K1+Na1)≤0.40 is satisfied.

5. The piezoelectric element according to claim 3, wherein K1/(K1+Na1)≥0.30 is satisfied.

6. The piezoelectric element according to claim 1, wherein K2/(K2+Na2)≥0.60 is satisfied.

7. The piezoelectric element according to claim 5, wherein K2/(K2+Na2)≤0.70 is satisfied.

8. The piezoelectric element according to claim 1, wherein 0.90<{Nb2/(K2+Na2+Nb2)}/{Nb1/(K1+Na1+Nb1)}<1.10 is satisfied, where
Nb1 is an average concentration of Nb in the lower piezoelectric body, and
Nb2 is an average concentration of Nb in the upper piezoelectric body.

9. The piezoelectric element according to claim 1, wherein a saturation polarization of the lower piezoelectric body is smaller than a saturation polarization of the upper piezoelectric body.

10. The piezoelectric element according to claim 9, wherein the saturation polarization of the lower piezoelectric body is 15.5 [μC/cm²] or less.

11. The piezoelectric element according to claim 9, wherein the saturation polarization of the upper piezoelectric body is 19.5 [μC/cm²] or more.

12. The piezoelectric element according to claim 1, wherein the upper piezoelectric body is thicker than the lower piezoelectric body.

13. A liquid ejecting head comprising:
the piezoelectric element according to claim 1;
a pressure chamber through which a liquid flows and in which a pressure is applied to the liquid by the piezoelectric element; and
a nozzle from which the liquid is ejected by the pressure applied in the pressure chamber.

14. A liquid ejecting apparatus comprising:
the liquid ejecting head according to claim 13; and
a control unit that controls an ejection operation from the liquid ejecting head.
